(19) United States
(12) Patent Application Publication
(10) Pub. No.: US 2007/0010103 A1
(43) Pub. Date: Jan. 11, 2007

(54) Nitric oxide reoxidation for improved gate leakage reduction of sion gate dielectrics

(75) Inventors: Thai Cheng Chua, Cupertino, CA (US); Christopher S. Olsen, Fremont, CA (US); Philip A. Kraus, San Jose, CA (US); Khaled Z. Ahmed, Anaheim, CA (US); Cory Czarnik, Saratoga, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/178,749

(22) Filed: Jul. 11, 2005

(51) Int. Cl. H01L 21/31; H01L 21/469

(52) U.S. Cl. 438/786

(57) ABSTRACT

A method of forming a silicon oxynitride gate dielectric. The method includes providing a structure comprising a silicon film formed on a substrate. The structure is exposed to a first plasma comprising a nitrogen source to incorporate nitrogen into the silicon film. The structure is oxidized in an atmosphere comprising nitric oxide to form a silicon oxynitride gate dielectric on the structure. The structure is then exposed to a second plasma comprising a nitrogen source.

### BACKGROUND OF THE INVENTION

1. Field of the Invention

Embodiments of the present invention generally relate to a method of forming a gate dielectric. More particularly, embodiments of the invention relate to a method of forming a silicon oxynitride (SiOₓN_{y}) gate dielectric.

2. Description of the Related Art

Integrated circuits are composed of many, e.g., millions, of devices such as field effect transistors. Field effect transistors typically include a source, a drain, and a gate stack. The gate stack typically includes a substrate, such as a silicon substrate, a gate dielectric, such as silicon dioxide (SiO₂), on the substrate, and a gate electrode, such as polycrystalline silicon, on the gate dielectric.

As integrated circuit sizes and the sizes of the transistors thereon decrease, the gate drive current required to increase the speed of the transistor has increased. Because the drive current increases as the gate capacitance increases, and capacitance is inversely proportional to the gate dielectric thickness, decreasing the dielectric thickness is one method of increasing the drive current.

Attempts have been made to reduce the thickness of SiO₂ gate dielectrics below 20 Å. However, it has been found that the use of thin SiO₂ gate dielectrics below 20 Å often results in undesirable effects on gate performance and durability. For example, boron from a boron doped gate electrode can penetrate through a thin SiO₂ gate dielectric into the underlying silicon substrate. Also, there is typically an increase in gate leakage, i.e., tunneling, with thin dielectrics thus increasing the amount of power consumed by the gate. Further, thin SiO₂ gate dielectrics may be susceptible to hot carrier damage, in which high energy carriers traveling across the dielectric can damage or destroy the gate. In addition, thin SiO₂ gate dielectrics may also be susceptible to negative bias temperature instability (NBTI), wherein the threshold voltage or drive current drifts with operation of the gate.

Consequently, there is a need for an alternative gate dielectric material that can be used in a large enough physical thickness to reduce current leakage density and still provide a high gate capacitance. In order to achieve this, the alternative gate dielectric material must have a dielectric constant that is higher than that of silicon dioxide. Typically, the thickness of such an alternative dielectric material layer is expressed in terms of the Equivalent Oxide Thickness (EOT). Thus, the EOT of an alternative dielectric layer in a particular capacitor is the thickness that the alternative dielectric layer would have if its dielectric constant were that of silicon dioxide.

One alternative dielectric layer that has been used to address the problems with thin SiO₂ gate dielectrics is a SiOₓN_{y} gate dielectric. The nitrogen in the SiOₓN_{y} gate dielectric layer blocks boron penetration into the underlying silicon substrate and raises the dielectric constant of the gate dielectric, allowing the use of a thicker dielectric layer.

A SiOₓN_{y} gate dielectric can be formed by incorporating nitrogen into a SiO₂ layer or forming a silicon nitride layer on a silicon substrate and incorporating oxygen into the layer via a reoxidation process involving either N₂O or O₂

However, as device geometry continues to shrink, there remains a need for a method of depositing silicon oxynitride dielectrics that have thinner Equivalent Oxide Thickness (EOT) with improved mobility.

### SUMMARY OF THE INVENTION

Embodiments of the present invention generally provide a method of forming a silicon oxynitride gate dielectric. The method includes providing a structure comprising a silicon film formed on a substrate. The structure is heated in an atmosphere comprising a nitrogen source to incorporate nitrogen into the silicon film. The structure is oxidized in an atmosphere comprising nitric oxide to form a silicon oxynitride gate dielectric on the structure. The structure is then exposed to a second plasma comprising a nitrogen source. In one embodiment, the structure is annealed after the structure is exposed to a plasma comprising a nitrogen source.

Another embodiment of the invention provides a method of forming a silicon oxynitride gate dielectric. The method includes providing a structure comprising a silicon film formed on a substrate. The structure is exposed to a first plasma comprising a nitrogen source to incorporate nitrogen into the silicon film. The structure is oxidized in an atmosphere comprising nitric oxide to form a silicon oxynitride gate dielectric on the structure. The structure is then exposed to a second plasma comprising a nitrogen source. In one embodiment, the structure is annealed after the structure is exposed to a plasma comprising a nitrogen source.

Another embodiment of the invention provides a method of forming a SiOₓN_{y} gate dielectric in an integrated processing system. The method includes introducing a substrate comprising silicon to a first processing chamber of an integrated processing system where the substrate is exposed to a first plasma comprising a nitrogen source. The substrate is transferred to a second processing chamber of the integrated processing system where the substrate is oxidized in an atmosphere comprising nitric oxide to form a SiOₓN_{y} gate dielectric on the substrate. The substrate is transferred to a third processing chamber of the integrated processing system where the substrate is exposed to a second plasma comprising a nitrogen source. In one embodiment, the substrate is transferred to a fourth processing chamber of the integrated processing system where the substrate is annealed at a temperature ranging between 700° C. and 1150° C. In another embodiment, the substrate is transferred to a fifth processing chamber of the integrated processing system where a polysilicon layer is deposited on the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top schematic view of an integrated processing system.

FIG. 2 is a flow chart depicting an embodiment of the invention.

FIG. 3 is a top schematic view of an integrated processing system.

FIG. 4 is a graph showing Gate Leakage (Jg) vs. Equivalent Oxide Thickness (EOT) for Thermal Nitridation (TN) and Plasma Nitridation (PN) processes with and without NO reoxidation.

FIG. 5 is a graph showing Gate Leakage (Jg) vs. Equivalent Oxide Thickness (EOT) for Thermal Nitridation (TN) or Plasma Nitridation (PN) processes followed by reoxidation with either O₂ or NO followed by Decoupled Plasma Nitridation (DPN) and Post Nitridation Anneal (PNA).

FIG. 6 is a graph showing Gate Leakage (Jg) vs. Equivalent Oxide Thickness (EOT) for Plasma Nitridation (PN) processes with either O₂ or NO reoxidation.

FIG. 7 is a graph showing Interface Trap Density (Dit) vs. Equivalent Oxide Thickness (EOT) for Thermal Nitridation (TN) and Plasma Nitridation (PN) processes with either NO or O₂ reoxidation.

FIG. 8 is a graph showing Interface Trap Density (Dit) vs. Equivalent Oxide Thickness (EOT) for Thermal Nitridation (TN) or Plasma Nitridation (PN) processes followed by reoxidation with either NO or O₂ followed by Decoupled Plasma Nitridation (DPN) and Post Nitridation Anneal (PNA).

### DETAILED DESCRIPTION

Embodiments of the invention include a method for depositing a SiOₓN_{y} gate dielectric. Gate stacks including the SiOₓN_{y} gate dielectric exhibit desirable electrical properties.

In one embodiment, a SiOₓN_{y} gate dielectric is formed by heating a structure comprising a silicon substrate in an atmosphere comprising a nitrogen source such as NH₃ to form a silicon nitride film on the silicon substrate. As defined herein, a silicon substrate includes single layer or single film silicon substrates, such as silicon wafers, or structures that include a silicon layer on one or more other layers. The silicon nitride film is then oxidized in an atmosphere containing nitric oxide to form the SiOₓN_{y} gate dielectric on the silicon substrate. The SiOₓN_{y} gate dielectric may then be exposed to a plasma containing a nitrogen source to incorporate more nitrogen into the SiOₓN_{y} gate dielectric to increase the dielectric constant. An additional Post Nitridation Anneal (PNA) step may be necessary to stabilize the film.

Heating the structure comprising a silicon substrate in an atmosphere comprising a nitrogen source such as NH₃ incorporates nitrogen into the silicon film such that the top surface of the silicon oxide film is nitrogen-doped thus forming a silicon nitride layer. The silicon nitride film preferably has a thickness of about 3 Å to about 15 Å, for example. The structure may be heated to a temperature of at least about 700° C. at a pressure of less than about 100 Torr, such as a pressure between about 0.1 Torr and about 100 Torr. Preferably, the structure is heated to a temperature between about 700° C. and about 1100° C., such as about 1050° C., at an NH₃ partial pressure of about 1 Torr. The structure may be heated for a time of between about 1 second and about 120 seconds or for a period of time sufficient to nitrogen dope the top surface of the silicon oxide film. Preferably, substantially no oxygen is incorporated into the structure while heating the structure in an atmosphere comprising NH₃. In another embodiment, nitrogen can be incorporated into the silicon film via a plasma nitridation process, for example, a Decoupled Plasma Nitridation (DPN) process.

The silicon nitride film is then oxidized in an atmosphere comprising nitric oxide to form the SiOₓN_{y} gate dielectric on the silicon substrate. The atmosphere comprising nitric oxide (NO) may contain hydrogen (H₂) and NO, NO and an inert gas, or combinations thereof. The SiOₓN_{y} gate dielectric may have a thickness of about 4 Å to about 16 Å, for example. In one embodiment, the silicon nitride layer may be exposed to an atmosphere comprising nitric oxide at a substrate temperature between about 700° C. and about 1150° C. and at a pressure between about 0.1 Torr and about 800 Torr for a time of between about 1 second and about 120 seconds. Preferably, the temperature is between about 750° C. and about 1000° C., and the pressure is between about 0.5 Torr and about 50 Torr.

After the structure is oxidized in an atmosphere comprising nitric oxide, the structure may be exposed to a plasma comprising a nitrogen source to incorporate more nitrogen into the SiOₓN_{y} gate dielectric. The nitrogen source may be nitrogen (N₂), NH₃, or combinations thereof. The plasma may further comprise an inert gas, such as helium, argon, or combinations thereof. The pressure during the plasma exposure of the substrate may be between about 1 mTorr and about 30 mTorr, such as between about 1 mTorr and about 10 mTorr. In a preferred embodiment, the nitridation process is a Decoupled Plasma Nitridation (DPN) process wherein the substrate is bombarded with atomic-N formed by co-flowing N₂ and a noble gas plasma such as argon. Besides N₂, other nitrogen-containing gases may be used to form the nitrogen plasma, such as H₃N hydrazines (e.g., N₂H₄ or MeN₂H₃), amines (e.g., Me₃N, Me₂NH or MeNH₂), anilines (e.g., C₅H₅NH₂), and azides (e.g., MeN₃ or Me₃SiN₃). Other noble gases that may be used in a DPN process include helium, neon, and xenon. The nitridation process proceeds at a time period from about 10 seconds to about 360 seconds, preferably from about 30 seconds to about 180 seconds, for example, about 120 seconds. Also, the nitridation process is conducted with a plasma power setting at about 900 watts to about 2,700 watts and a pressure at about 1 mTorr to about 100 mTorr. The nitrogen has a flow rate from about 0.1 slm to about 1.0 slm. The individual and total gas flows of the processing gases may vary based upon a number of processing factors, such as the size of the processing chamber, the temperature of the processing chamber, and the size of the substrate being processed.

One example of a Decoupled Plasma Nitridation process reactor that can be used with this invention is described in U.S. Patent Application Publication No. 2004/0242021, entitled “Method And Apparatus For Plasma Nitridation Of Gate Dielectrics Using Amplitude Modulated Radio Frequency Energy,” assigned to Applied Materials, Inc., published Dec. 2, 2004 and herein incorporated by reference to the extent not inconsistent with the invention. Examples of suitable DPN chambers include the DPN Centura™, which is commercially available from Applied Materials, Inc., Santa Clara, Calif.

Preferably, the SiOₓN_{y} gate dielectric described herein comprises at least 5 atomic percent nitrogen. In one embodiment, the SiOₓN_{y} gate dielectric comprises between about 5 atomic percent nitrogen and about 50 atomic percent nitrogen.

Optionally, the structure is annealed after exposure to the plasma. In one embodiment, the structure is annealed in an atmosphere comprising O₂ The partial pressure of O₂ during the annealing step may be less than 50 Torr, such as between about 10 mTorr and about 50 Torr. The structure may be annealed at a temperature of between about 700° C. and about 1150° C., such as at a temperature between about 950° C. and about 1150° C. In another embodiment, the structure is annealed in an inert atmosphere and then annealed in an atmosphere comprising O₂ as described above. In another embodiment, the inert atmosphere contains a trace amount of O₂. The structure may be annealed in the inert or reducing atmosphere at a temperature of between about 700° C. and about 1150° C., such as at a temperature between about 950° C. and about 1150° C. For example, the structure may be annealed at a temperature of about 1000° C. in an atmosphere comprising N₂ at an N₂ partial pressure of between about 1 Torr and about 760 Torr.

After the structure is exposed to the plasma and optionally annealed, a gate electrode, such as a polysilicon layer, may be deposited on the SiOₓN_{y} gate dielectric to complete a gate stack.

In another embodiment, the silicon substrate is exposed to a plasma comprising a nitrogen source in a reduced pressure of 5-100 mTorr to incorporate nitrogen into the silicon film to form the silicon nitride film.

Integrated Processing Sequence

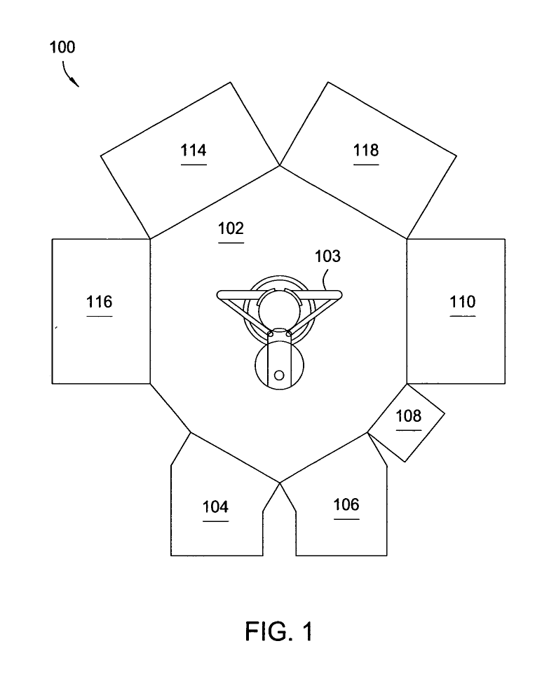

In a further embodiment, a SiOₓN_{y} gate dielectric may be formed on a substrate in an integrated processing system, such as an integrated semiconductor processing system, in a method in which the substrate is not removed from the integrated processing system until after the SiOₓN_{y} gate dielectric is formed. An example of an integrated processing system 100 that may be used is the Gate Stack Centura® system, available from Applied Materials, Inc. of Santa Clara, Calif., which is shown in FIG. 1. The integrated processing system 100 includes a central transfer chamber 102, transfer robot 103, load locks 104, 106, a cool down chamber 108, a rapid thermal processing (RTP) chamber 110, a plasma processing chamber 116, a rapid thermal processing (RTP) chamber 114, and a CVD processing chamber 118. CVD processing chamber 118 is a low pressure chemical vapor deposition chamber (LPCVD), such as a POLYgen chamber, available from Applied Materials. RTP chambers 110 and 114 are chambers that can run a rapid thermal annealing (RTA) process at a reduced or ultra-low pressure (e.g. about equal to or less than 10 Torr).

The processing conditions for embodiments in which the SiOₓN_{y} gate dielectric is formed in an integrated processing system are the same as the processing conditions described above for the formation of the silicon nitride film and the SiOₓN_{y} gate dielectric. For example, in one embodiment a structure comprising a silicon film on a silicon substrate is exposed to a plasma comprising a nitrogen source in a first processing chamber of the integrated processing system to incorporate nitrogen into the silicon film thus forming a silicon nitride film. The structure is then transferred to a second processing chamber of the integrated processing system and oxidized in an atmosphere containing nitric oxide. The structure is then transferred to a third processing chamber of the integrated processing system and exposed to a plasma comprising a nitrogen source. Optionally, after exposing the structure to the plasma, the structure may be transferred to a fourth processing chamber of the integrated processing system where the structure is annealed.

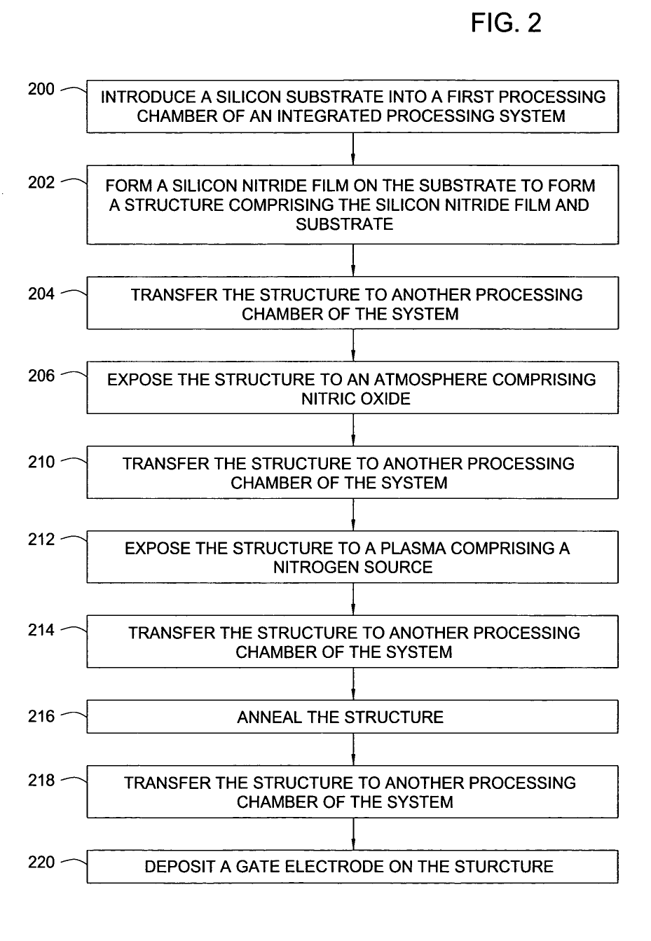

In another embodiment, a substrate is introduced into an integrated processing system and a silicon nitride film, a SiOₓN_{y} gate dielectric, and a gate electrode are deposited on the substrate without removing the substrate from the integrated processing system. This embodiment will be described below with respect to FIGS. 1 and 2.

A silicon substrate is introduced into the integrated processing system 100 via a load lock 104 or 106 and placed in a plasma processing chamber 116, where a silicon nitride film is formed on the silicon substrate, as shown in steps 200 and 202 of FIG. 2. The structure is then transferred to a RTP chamber 114 where it is oxidized via exposure to a nitric oxide atmosphere, as shown in steps 204 and 206 to form the silicon oxynitride layer. The structure is then transferred to a plasma processing chamber 116, where it is exposed to a plasma comprising a nitrogen source to incorporate more nitrogen into the silicon oxynitride film as shown in steps 210 and 212. Optionally, the structure is transferred to RTP chamber 110 where the structure is annealed, as shown in steps 214 and 216. The structure can be annealed in a commercially available reduced pressure RTP chamber hardware such as XE, XE Plus or Radiance made by Applied Materials, Inc. The structure is then transferred to CVD processing chamber 118, as shown in step 218, and a gate electrode, such as a polysilicon layer or an amorphous silicon layer is deposited on the structure, as shown in step 220. The gate electrode may also comprise a metal electrode comprising titanium, titanium nitride, tantalum, tantalum nitride, tungsten, tungsten nitride, and other refractory metals or other suitable electrode materials. After formation of the gate electrode, the structure is transferred to a cool down chamber 108 and the structure is then removed from the integrated processing system 100 via a load lock 104 or 106.

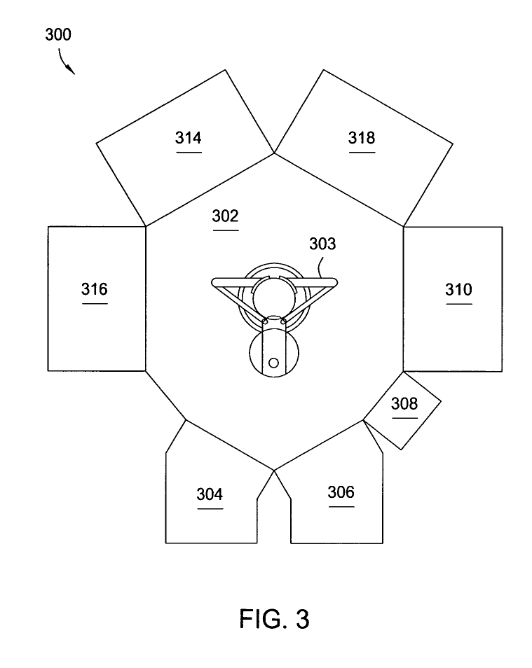

In the embodiment described above with respect to FIGS. 1 and 2, the silicon nitride film is oxidized in the RTP chamber 114 in one step and the structure is annealed in the same RTP chamber 114 in another step. In an alternative embodiment, a second plasma processing chamber and a second RTP chamber are configured on an integrated processing system 300, as shown in FIG. 3, and the silicon nitride film is formed in one plasma processing chamber in one step and exposed to a second plasma in a different plasma processing chamber. The integrated processing system 300 includes a central transfer chamber 302, transfer robot 303, load locks 304, 306, a cool down chamber 308, a first rapid thermal processing (RTP) chamber 310, a first plasma processing chamber 316, a second rapid thermal processing (RTP) chamber 314, and a second plasma processing chamber 318.

In another embodiment, a silicon substrate is introduced into the integrated processing system 300 via a load lock 304 or 306 and placed in a first plasma processing chamber 316, where a silicon nitride film is formed on the silicon substrate. The structure, including the substrate and the silicon nitride film, is transferred to a first rapid thermal processing (RTP) chamber 314 where it is oxidized. The structure is then transferred to a second plasma processing chamber 318, where it is exposed to a plasma comprising a nitrogen source to incorporate more nitrogen into the SiOₓN_{y} gate dielectric. Optionally, the structure is transferred to a second RTP chamber 310 where the structure is annealed. After the structure is annealed, the structure is transferred to cool down chamber 308 or transferred out of the integrated processing system 300 via load lock 304 or 306 to a processing chamber (not shown) external to the integrated processing system such as a low pressure chemical vapor deposition chamber (LPCVD), atomic layer epitaxy (ALE), thermal decomposition methods, or other methods known in the art for depositing a gate electrode, such as a polysilicon layer or an amorphous silicon. The polysilicon layer generally contains dopants such as boron, phosphorous or arsenic. The gate electrode can also be a metal layer.

While the above embodiments are described with respect to FIGS. 1, 2 and 3, it is recognized that other integrated processing systems may be used with the embodiments described herein.

Performance of SiOₓN_{y} Gate Dielectrics

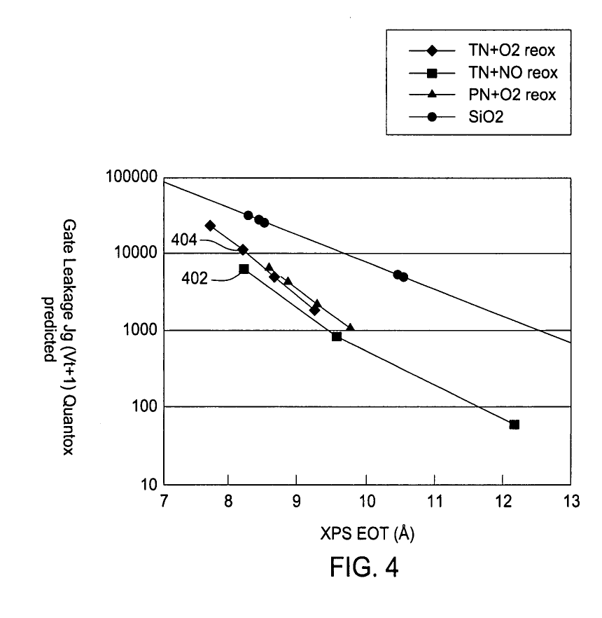

FIG. 4 shows the Gate Leakage (Jg) versus Equivalent Oxide Thickness (EOT) for Thermal Nitridation (TN) and Plasma Nitridation (PN) processes with either O₂ or NO reoxidation for gate stacks including a structure comprising a SiOₓN_{y} gate dielectric formed according to embodiments of the invention as well as for gate stacks formed according to other methods. The following process sequences were compared in FIG. 4: a silicon substrate was heated in an NH₃ atmosphere to form a 10 Å silicon nitride layer on the substrate and reoxidized in an oxygen atmosphere; a silicon substrate was heated in a NH₃ atmosphere to form a 10 Å silicon nitride layer on the substrate and reoxidized in a nitric oxide atmosphere; and a silicon substrate was plasma treated in a nitrogen atmosphere to form a 10 Å silicon nitride layer and reoxidized in an oxygen atmosphere.

The results in FIG. 4 illustrate that at the same EOT, nitric oxide reoxidation shows additional gate leakage reduction over O₂ reoxidation for a TN film. For example, as shown at point 402, a silicon substrate nitrided by thermal nitridation followed by reoxidation with nitric oxide exhibits an approximately 50% reduction in gate leakage compared to a silicon substrate nitrided by thermal nitridation followed by reoxidation with nitric oxide as shown at point 404,. The silicon oxynitride film at point 402 has an EOT value of 8.2 Å, no change from the silicon oxynitride value at point 404. Furthermore, the nitric oxide reoxidized film also demonstrates additional gate leakage reduction over Plasma Nitridation followed by O₂ reoxidation.

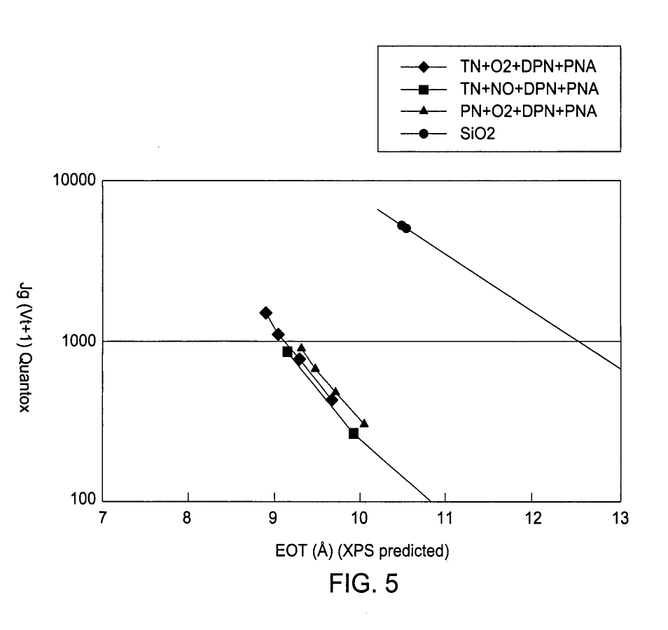

FIG. 5 shows the Gate Leakage versus Equivalent Oxide Thickness (EOT) for Thermal Nitridation (TN) and Plasma Nitridation (PN) processes with either O₂ or NO reoxidation followed by Decoupled Plasma Nitridation (DPN) and Post Nitridation Anneal (PNA) for gate stacks including a structure comprising a SiOₓN_{y} gate dielectric formed according to embodiments of the invention as well as for gate stacks formed according to other methods. The following process sequences were compared in FIG. 5: a silicon substrate was heated in an atmosphere comprising NH₃ to form a silicon nitride layer on the substrate, reoxidized with oxygen, exposed to a DPN, and then a PNA; a silicon substrate was heated in an atmosphere comprising NH₃ to form a silicon nitride layer on the substrate, reoxidized with nitric oxide, exposed to a DPN, and then a PNA; a silicon substrate was exposed to a DPN to form a silicon nitride layer on the substrate, reoxidized with oxygen, exposed to a DPN, and then a PNA. The PNA was performed first at 1000° C. for 30 seconds in atmosphere with an O₂ partial pressure of 15 mTorr and then second with an O₂ partial pressure of 0.5 Torr for a period of 30 seconds.

The results in FIG. 5 illustrate that even with the addition of the DPN and PNA steps to the TN and reoxidation process, the NO reoxidation split again shows further gate leakage reduction over the O₂ reoxidation split, at the same EOT.

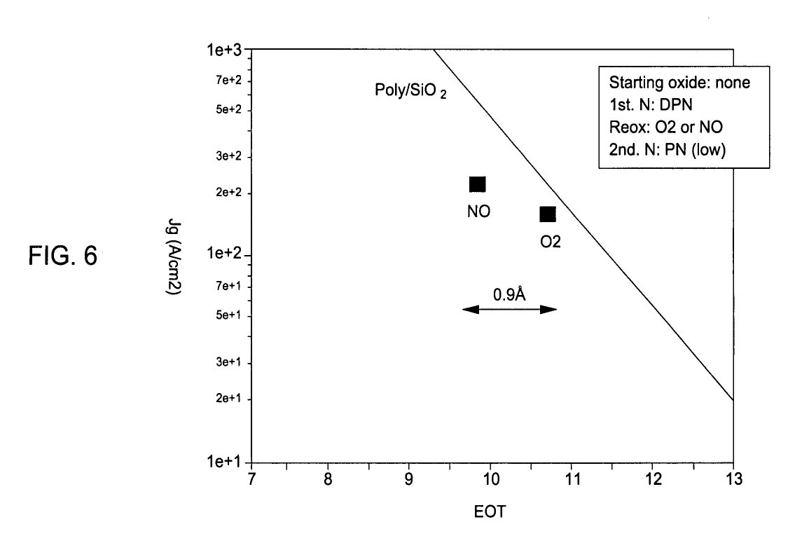

FIG. 6 shows Gate Leakage vs. Equivalent Oxide Thickness (EOT) for Plasma Nitridation (PN) processes with O₂ and NO reoxidation. This MOSCAP data shows that NO reoxidation on a starting plasma nitridation process achieves lower EOT and increased gate leakage reduction (Jg) relative to the SiO₂ reference line.

These results demonstrate that a process in which a structure is heated in an atmosphere comprising NH₃ and then reoxidized with nitric oxide has a more desirable low gate leakage than a structure that is either heated in an atmosphere comprising NH₃ or treated with a plasma comprising nitrogen followed by reoxidation with O₂. Furthermore, a process in which a structure is treated with a plasma comprising nitrogen, reoxidized with nitric oxide, treated with a plasma comprising nitrogen, and then annealed, as described in embodiments of the invention, can provide gate stacks that have a more desirable low gate leakage than a process which uses O₂ in the reoxidation step.

Another challenge is maintaining an interface of reasonably good quality between the Si channel and the gate dielectric. One parameter which indicates the quality of this interface is the density of interface traps (Dit). The reduction of Dit through process optimization is one goal of gate dielectric process development. It is know in the art that an excessive amount of nitrogen atoms bonded at the Si interface will lead to a large Dit. Larger Dit degrades metal oxide semiconductor field-effect transistor (MOSFET) performance and contributes to reduced device lifetimes for MOSFET in the case of NBTI testing.

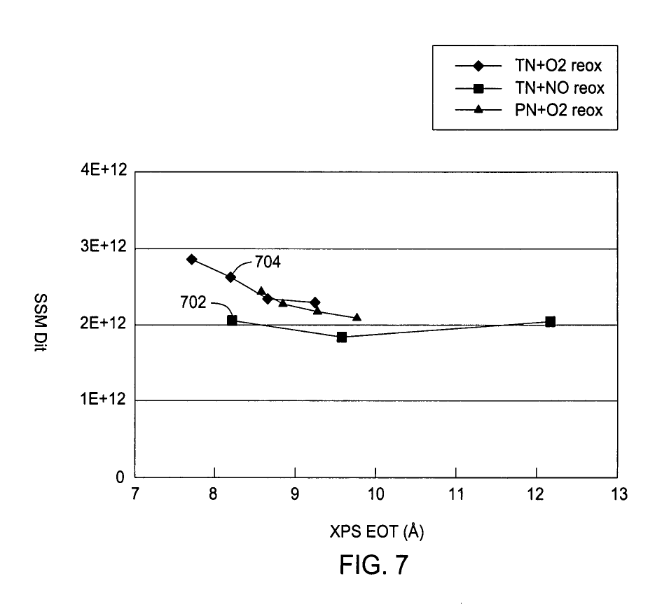

FIG. 7 is a graph showing Dit vs. Equivalent Oxide Thickness (EOT) for Thermal Nitridation and Plasma Nitridation (PN) processes with either NO or O₂. For example, as shown at point 702, a silicon substrate nitrided by thermal nitridation followed by reoxidation with nitric oxide exhibits an approximately 25% reduction in Dit relative to O₂ reoxidation of a thermally nitrided (TN) starting film as shown at point 704. The silicon oxynitirde film at point 702 has an EOT value of approximately 8.2 Å, no change from the EOT value at point 704. The results of FIG. 7 show that the interface trap density (Dit) is approximately 25% lower for the NO reoxidized film compared to the O₂ reoxidized film. The results also demonstrate that a silicon substrate nitrided by thermal nitridation followed by reoxidation with nitric oxide exhibits a reduction in Dit relative to O₂ reoxidation of a plasma nitrided (PN) starting film.

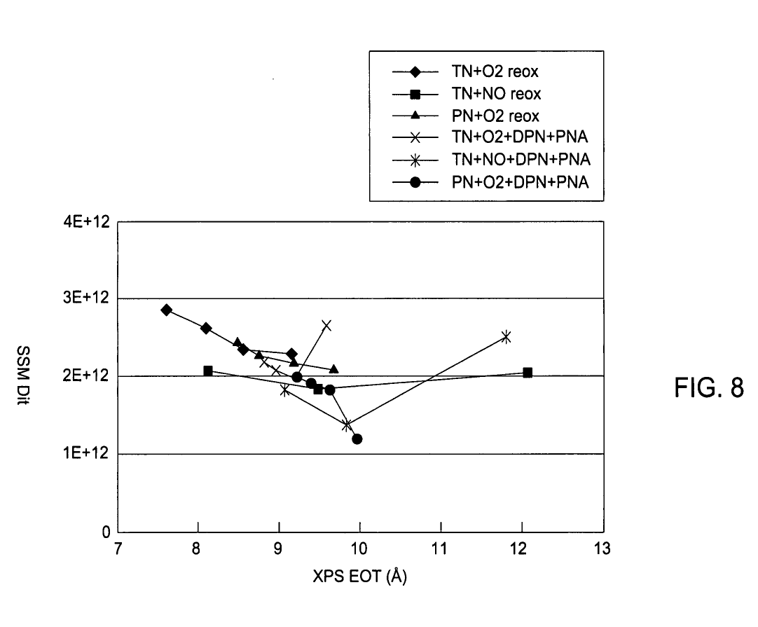

Further, as shown in FIG. 8, the results are similar for a four step process. FIG. 8 is a graph showing Interface Trap Density (Dit) vs. Equivalent Oxide Thickness (EOT) for Thermal Nitridation or Plasma Nitridation (PN) processes followed by reoxidation with NO or O₂ followed by Decoupled Plasma Nitridation (DPN) and Post Nitridation Anneal (PNA). The NO reoxidation split again shows lower Dit relative to the O₂ reoxidation split at a given EOT, and in particular for an EOT less than 10 Å

While the foregoing is directed to embodiments of the present invention, other and further embodiments of the invention may be devised without departing from the basic scope thereof, and the scope thereof is determined by the claims that follow

1. A method of forming a silicon oxynitride gate dielectric, comprising:
providing a structure comprising a silicon film formed on a substrate;
heating the structure in an atmosphere comprising a nitrogen source to incorporate nitrogen into the silicon film;
oxidizing the structure in an atmosphere comprising nitric oxide to form a silicon oxynitride gate dielectric on the structure; and
exposing the structure to a plasma comprising a nitrogen source.

2. The method of claim 1, further comprising annealing the substrate at a temperature ranging between 700° C. and 1150° C. after exposing the structure to a plasma.

3. The method of claim 1, wherein the oxidizing the structure in an atmosphere comprising nitric oxide comprises oxidizing the structure at a substrate temperature between about 700° C. and about 1150° C. and at a pressure between about 0.1 Torr and about 800 Torr for a time of between about 1 second and about 120 seconds.

4. The method of claim 3 wherein the temperature is between about 750° C. and about 1000° C., and the pressure is between about 0.5 Torr and about 50 Torr.

5. The method of claim 1, wherein the nitrogen source is selected from the group consisting of N₂, NH₃, and combinations thereof.

6. The method of claim 1, wherein the exposing the structure to a plasma comprising a nitrogen source occurs at a pressure ranging between about 1 mTorr and about 5 Torr.

7. The method of claim 1, wherein a thickness of the SiOₓN_{y} gate dielectric is between about 7 Å to about 15 Å Equivalent Oxide Thickness.

8. The method of claim 1, wherein the nitrogen incorporated in the exposing the structure to a plasma forms a nitrogen concentration peak that occurs at the top surface of the SiOₓN_{y} gate dielectric.

9. A method of forming a SiOₓN_{y} gate dielectric, comprising:
providing a structure comprising a silicon film formed on a substrate;
exposing the structure to a first plasma comprising a nitrogen source to incorporate nitrogen into the silicon film;
oxidizing the structure in an atmosphere comprising nitric oxide to form a SiOₓN_{y} gate dielectric; and
exposing the structure to a second plasma comprising a nitrogen source.

10. The method of claim 9, further comprising annealing the structure at a temperature ranging between 700° C. and 1150° C. after exposing the structure to a second plasma.

11. The method of claim 9, wherein the oxidizing the structure in an atmosphere comprising nitric oxide comprises oxidizing the structure at a substrate temperature between about 700° C. and about 1150° C. and at a pressure between about 0.1 Torr and about 800 Torr for a time of between about 1 second and about 120 seconds.

12. The method of claim 9, wherein the nitrogen source is selected from the group consisting of N₂, NH₃, and combinations thereof.

13. The method of claim 9, wherein the exposing the structure to a plasma comprising a nitrogen source occurs at a pressure ranging between about 1 mTorr and about 5 Torr.

14. The method of claim 9, wherein a thickness of the SiOₓN_{y} gate dielectric is between about 7 Å to about 15 Å Equivalent Oxide Thickness.

15. The method of claim 9, wherein the nitrogen incorporated into the SiOₓN_{y} gate dielectric structure has a nitrogen concentration equal to or greater than 5% nitrogen.

16. The method of claim 9, wherein the nitrogen incorporated in the exposing the structure to a plasma forms a nitrogen concentration peak that occurs at the top surface of the SiOₓN_{y} gate dielectric.

17. A method of forming a SiOₓN_{y} gate dielectric in an integrated processing system comprising:
introducing a substrate comprising silicon to an integrated processing system;
exposing the substrate to a first plasma comprising a nitrogen source;
transferring the substrate to a second processing chamber of the integrated processing system;
oxidizing the substrate in an atmosphere containing nitric oxide to form a SiOₓN_{y} gate dielectric on the substrate;
transferring the substrate to a third processing chamber of the integrated processing system; and then
exposing the substrate to a second plasma comprising a nitrogen source.

18. The method of claim 17, further comprising:
transferring the substrate to a fourth processing chamber of the integrated processing system; and then
annealing the substrate at a temperature ranging between 700° C. and 1150° C. after exposing the substrate to a plasma.

19. The method of claim 18, further comprising:
transferring the substrate to a fifth processing chamber of the integrated processing system after annealing the substrate; and
depositing a polysilicon layer on the SiOₓN_{y} gate dielectric in the fifth processing chamber.

20. The method of claim 18, further comprising:
transferring a substrate to a fifth processing chamber external to the integrated processing system after exposing the substrate to a second plasma; and
depositing a polysilicon layer on the SiOₓN_{y} gate dielectric in the fifth processing chamber.
